(19) United States
(12) Patent Application Publication
(10) Pub. No.: US 2008/0073032 A1
(43) Pub. Date: Mar. 27, 2008

(54) Stage for plasma processing apparatus, and plasma processing apparatus

(76) Inventors: Akira Koshiishi, Nirasaki-Shi (JP); Shinji Himori, Nirasaki-Shi (JP); Shoichiro Matsuyama, Nirasaki-Shi (JP)

Correspondence Address: SMITH, GAMBRELL & RUSSELL, LLP;Suite 800, 1850 M. Street, N.W., Washington, DC, 20036, US

(21) Appl. No.: 11/889,338

(22) Filed: Aug. 10, 2007

Related U.S. Application Data
(60) Provisional application No. 60/844,371, filed on Sep. 14, 2006.

(30) Foreign Application Priority Data
Aug. 10, 2006 (JP) 2006-217871

(51) Int. Cl. H01L 21/306

(52) U.S. Cl. 156/345.51

(57) ABSTRACT

[Object] To provide a stage for plasma processing apparatus, the stage being capable of improving uniformity of electric field strength in a plasma so as to enhance an in-plane uniformity of a plasma process to a substrate, and to provide a plasma processing apparatus provided with this stage.

[Means for Solving the Problem] A stage 1 for a plasma processing apparatus 2 comprises: a conductive member 21 serving as an electrode for generating a plasma or the like; a dielectric layer 22 covering a center part of an upper surface of the conductive member, for making uniform a radiofrequency electric field applied to a plasma through a substrate to be processed (wafer W); and an electrostatic chuck laminated on the dielectric layer 22, the electric chuck having a plurality of electrode films embedded therein, the electrode films being separated apart from each other in a radial direction of the stage to allow passage of a radiofrequency. An outer edge of the dielectric layer 22 is positioned right below or outside an inner edge of at least one separation area 23c of the separated electrode films 23b and 23d. The separated electrode films 23b and 23d are insulated to each other as to a radiofrequency.

### FIELD OF THE INVENTION

The present invention relates to: a stage for placing thereon a substrate to be processed, such as a semiconductor wafer, which is to be subjected to a plasma process; and a plasma processing apparatus including the stage.

### BACKGROUND ART

In manufacturing step of a semiconductor device, there are many steps for processing a substrate by making a process gas plasma, such as a dry etching step and an ashing step. As a plasma processing apparatus for these processes, a plasma processing apparatus of the following type is prevalently used, for example. Namely, there are disposed a pair of upper and lower parallel plate electrodes that are opposed to each other, and by applying a radiofrequency to a space between these electrodes to make plasma a process gas which has been introduced into the apparatus, a semiconductor wafer (referred to as “wafer” below) placed on the lower electrode is subjected to a plasma process.

Recently, there has been a tendency that the plasma process has to be conducted under a state in which ion energy in plasma is low, while electron density thereof is high, i.e., the “low energy and high density plasma” state is required. Thus, there is a case in which a radiofrequency of e.g., 100 MHz is used for generating a plasma, which is significantly higher than a conventional one (e.g., about 10 MHz or the like). However, when the frequency of a radiofrequency is raised, electric field strength is prone to be increased in a central region of a surface of an electrode, which region corresponds to a central region of a wafer, while the electric field strength is prone to be reduced in a circumferential region of the surface of the electrode. Such non-uniform distribution of the electric field strength causes non-uniform electron density of a plasma to be generated, whereby a processing speed varies according to a position within the wafer. Thus, a problem may occur in that a satisfactory process result as to an in-plane uniformity cannot be obtained.

In order to cope with this problem, in Patent Document 1, a dielectric layer made of ceramics or the like is embedded in a central part of a surface of one electrode, the surface facing the other electrode, so that electric field strength density is made uniform, whereby an in-plane uniformity of a plasma process can be improved.

Such embedment of a dielectric layer is described with reference to FIG. 13(a). When a radiofrequency is applied to a lower electrode 91 of a plasma processing apparatus 9 from a radiofrequency power source 93, the radiofrequency is propagated through a surface of the lower electrode 91 to reach an upper part thereof by a skin effect, and then is directed to a central part along a surface of a wafer W. Herein, a part of the radiofrequency leaks to the lower electrode 91, and then flows outward inside the lower electrode 91. As compared with the other parts, the radiofrequency can more deeply plunge into a part where a dielectric layer 94 for making uniform a plasma is provided, so as to generate a hollow cylindrical resonance of TM mode. Thus, an electric field supplied from the upper surface of the wafer W to the plasma is lowered at a central part of the wafer W, to thereby make uniform the electric field within the surface of the wafer W. The reference number 12 depicts an upper electrode, and PZ depicts a plasma.

A plasma process is often conducted under a reduced pressure such as a vacuum atmosphere. In this case, as shown in FIG. 13(b), an electrostatic chuck 95 is generally used to fix the wafer W. The electrostatic chuck 95 has a structure in which a conductive electrode film 96 is interposed between upper and lower dielectric layers formed by thermally spraying, e.g., alumina. By applying high-voltage direct-current power to the electrode film 96 from a high-voltage direct-current power source 97 to generate a Coulomb force on a surface of the dielectric layer, the wafer W can be electrostatically absorbed and fixed.

However, when the wafer W is subjected to a plasma process in the state that the electrostatic chuck 95 is arranged on the lower electrode 11 having the dielectric layer 94 embedded therein for lowering electric potential of the plasma, the radiofrequency cannot transmit through the electrode film 96 in the electrostatic chuck 95, and there is generated an outward flow of the radiofrequency in the electrode film 96. In other words, because of the existence of the electrode film 96 for the electrostatic chuck, the dielectric layer 94 cannot be seen from the plasma (influence of the dielectric layer 94 on the plasma is blocked), and thus the effect by the dielectric layer 94 of lowering the electric potential of the plasma cannot be produced. As a result, an electric potential of the plasma above the central part of the wafer W becomes high, while an electric potential of the plasma above the circumferential part of the wafer W becomes low. Thus, a process speed differs between the central part of the wafer W and the circumferential part thereof, which impairs an in-plane uniformity of a plasma process such as etching.

[Patent Document 1] JP2004-363552A: page 15, sections 84 and 85

### DISCLOSURE OF THE INVENTION

### Problems to be Solve by the Invention

Taking account of the above problem, the present invention has been made to effectively solve the same. The object of the present invention is to provide a stage for a plasma processing apparatus, the stage being capable of improving uniformity of electric field strength in a plasma so as to enhance an in-plane uniformity of a plasma process to a substrate, and to provide a plasma processing apparatus including such a stage.

### Means for Solving the Problem

The present invention is a stage for a plasma processing apparatus, the stage being configured to place on a placing surface thereof a substrate to be processed, the stage comprising: a conductive member connected to a radiofrequency power source, the conductive member serving as an electrode for generating a plasma and/or as an electrode for drawing ions from a plasma; a dielectric layer covering a center part of an upper surface of the conductive member, for making uniform a radiofrequency electric field applied to a plasma through a substrate to be processed placed on the placing surface; and an electrostatic chuck laminated on the dielectric layer, the electric chuck having a plurality of electrode films embedded therein, the electrode films being separated apart from each other in a radial direction of the stage to allow passage of a radiofrequency; wherein an outer edge of the dielectric layer is positioned right below or outside an inner edge of at least one separation area of the separated electrode films, and the separated electrode films are insulated to each other as to a radiofrequency.

Further, a plurality of dielectric layers may be laminated as the dielectric layer, a lower dielectric layer of the plurality of dielectric layers may be located such that an outer edge of the lower dielectric layer is positioned inside relative to that of an upper dielectric layer, and the number of the separated electrode films may be larger than the number of the laminated dielectric layers at least by one.

In addition, in the stage of the same type, there may be disposed an electrostatic chuck laminated on the dielectric layer, the electric chuck having a hole formed in a position corresponding to a center part of the stage to allow passage of a radiofrequency, and the dielectric layer may be positioned below the hole.

The dielectric layer may be formed into a columnar shape to generate a hollow cylindrical resonance of TM mode. A thickness of a circumferential part of the dielectric layer may be smaller than a thickness of a central part of the dielectric layer. A frequency of the radiofrequency supplied from the radiofrequency power source is not less than 13 MHz.

### EFFECT OF THE INVENTION

According to the present invention, since the expression 6/z>1,000 is satisfied, the radiofrequency propagated through the substrate to be processed can pass through the electrode film to plunge into a lower part of the dielectric layer for making uniform a radiofrequency electric field applied to the plasma through the substrate to be processed. As a result, even when there is disposed the electrostatic chuck, by utilizing the dielectric layer to generate a hollow cylindrical resonance of TM mode, it is possible to lower the electric field in a central part which is supplied from the upper surface of the substrate to be processed to the plasma. Namely, in the electric field strength distribution, it is possible to flatten a chevron-like area of a high electric field strength. As a result, an in-plane uniformity of a plasma process, such as an etching process, can be enhanced.

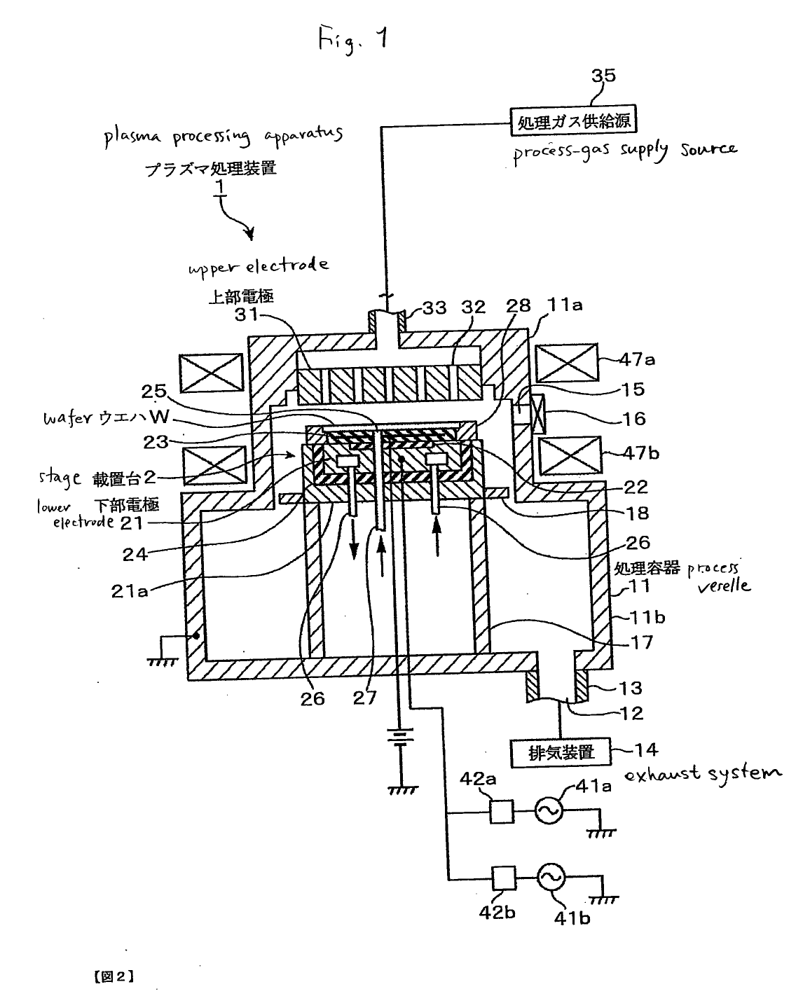

An embodiment of the stage according to the present invention, which is applied to an etching apparatus as a plasma processing apparatus, is described with reference to FIG. 1. A plasma processing apparatus 1 shown in FIG. 1 is a RIE (Reactive Ion Etching) plasma processing apparatus. The plasma processing apparatus 1 includes: a process vessel 11 of a vacuum chamber, an inside of which is a hermetically sealed space; a stage 2 disposed on a central part of a bottom surface of the process vessel 11; and an upper electrode 31 which is disposed above the stage 2 and opposed thereto.

The process vessel 11 has a cylindrical upper chamber 11a of a smaller diameter, and a cylindrical lower chamber 11b of a larger diameter. The upper chamber 11a and the lower chamber 11b are communicated with each other, and the overall process vessel 11 can be air-tightly closed. The upper chamber 11a contains the stage 2, the upper electrode 31, and so on. The lower chamber 11b contains a support case 17 that supports the stage 2 and houses pipes or the like. An exhaust system 14 is connected via an exhaust pipe 13 to an exhaust port 12 formed in a bottom surface of the lower chamber 11b. A pressure adjusting part, not shown, is connected to the exhaust system 14. Based on a signal from a control part, not shown, the pressure adjusting part is configured to evacuate the whole inside of the process vessel 11, and to maintain the same at a desired vacuum degree. A loading/unloading port 15 for a wafer W as a substrate to be processed is formed in a side surface of the upper chamber 11a. The loading/unloading port 15 is capable of being opened and closed by a gate valve 16. The process vessel 11 is formed of a conductive material such as aluminum, and is grounded.

The stage 2 includes: a lower electrode 21 for generating a plasma, which is a conductive member made of, e.g., aluminum; a dielectric layer 22 for adjusting an electric field to be uniform, the dielectric layer 22 being embedded in the lower electrode 21 to cover a center part of an upper surface of the lower electrode 21; and an electrostatic chuck 23 for fixing a wafer W. The lower electrode 21, the dielectric layer 22, and the electrostatic chuck 23 are stacked in this order from below. The lower electrode 21 is secured on a support table 21a disposed on the support case 17, via an insulating member 24, and in a sufficiently electrically floating situation relative to the process vessel 11.

A cooling medium passage 26 through which a cooling medium passes is formed in the lower electrode 21. When the cooling medium flows in the cooling medium passage 26, the lower electrode 21 is cooled. Thus, a wafer W placed on a placing surface can be cooled to a desired temperature.

The electrostatic chuck 23 is provided with a through-hole 25 for discharging a heat-conductive backside gas for elevating heat transfer rate between a surface of the electrostatic chuck 23 on which a wafer W is placed, i.e., a placing surface, and a rear surface of the wafer W. The through-hole 25 is communicated with a gas passage 27 formed in the lower electrode 21. A backside gas such as helium (He), which has been supplied through the gas passage 27 from a gas supply part, not shown, is discharged from the through-hole 25.

To the lower electrode 21, there are connected a first radiofrequency power source 41a and a second radiofrequency power source 41b via matching boxes 42a and 42b, respectively. The first radiofrequency power source 41a supplies a radiofrequency of, e.g., 100 MHz, and the second radiofrequency power source 41b supplies a radiofrequency of 3.2 MHz which is lower than the radiofrequency supplied from the first radiofrequency power source 41a. As described below, the radiofrequency supplied from the first radiofrequency power source 41a serves to make a process gas plasma. The radiofrequency supplied from the second radiofrequency power source 41b serves to apply a bias electric power to a wafer W so as to draw ions from a plasma into a surface of the wafer W.

A focus ring 28 is arranged on a periphery of the upper surface of the lower electrode 21 to surround the electrostatic chuck 23. The focus ring 28 functions to adjust a condition of a plasma in a region outside the circumference (edge) of the wafer W. To be specific, by making larger an area of the plasma than that of the wafer W, the focus ring 28 further elevates uniformity in etching speed in a plane of the wafer.

A baffle plate 18 is disposed on an outside surface of a lower part of the support table 21a. A process gas in the upper chamber 11a flows into the lower chamber 11b through a clearance formed between the baffle plate 18 and a wall of the upper chamber 11a. Namely, the baffle plate 18 serves as a current plate for rectifying the process gas.

The upper electrode 31 is formed hollow. In a lower surface of the upper electrode 31, a large number of gas-supplying holes 32 are formed in a uniformly dispersed manner, for example, for dispersedly supplying a process gas into the process vessel 11, to thereby constitute a gas showerhead. A gas-introducing pipe 33 is disposed on a center part of an upper surface of the upper electrode 31. The gas-introducing pipe 33 passes through a center part of an upper surface of the process vessel 11, and is connected to a process-gas supplying source 35 on an upstream side. The process-gas supplying source 35 has a not-shown control mechanism for controlling a feed rate of a process gas. Thus, feed ON/OFF of a process gas to the plasma processing apparatus 1, and increase/decrease of a feed rate of the process gas can be controlled. Since the upper electrode 31 is secured on a wall part of the upper chamber 11a, a conductive path is formed between the upper electrode 31 and the process vessel 11.

Two multipole ring magnets, i.e., an upper multipole ring magnet 47a and a lower multipole ring magnet 47b are arranged around the upper chamber 11a such that the loading/unloading port 15 is positioned between the multipole ring magnets 47a and 47b. Each of the multipole ring magnets 47a and 47b is formed of a plurality of anisotropic segment columnar magnets which are attached to a ring-shaped magnetic casing. Magnetic poles of the adjacent segment columnar magnets are oriented in the mutually reverse direction. Owing to this arrangement, lines of magnetic force are formed between the adjacent segment magnets, and a magnetic field is formed in an area surrounding a process space between the upper electrode 31 and the lower electrode 21, so that a plasma can be confined within the process space. However, it is possible to adopt a structure of the apparatus which does not have the multipole ring magnets 47a and 47b.

By the above structure of the apparatus, a pair of parallel plate electrodes are formed by the lower electrode 21 and the upper electrode 31, in the process vessel 11 (upper chamber 11a) of the plasma processing apparatus 1. After the inside of the process vessel 11 is adjusted at a predetermined pressure, by supplying radiofrequencies from the radiofrequency power sources 41a and 41b, while a process gas is introduced into the process vessel 11, the process gas is made plasma. The radiofrequencies flow through the lower electrode 21, the plasma, the upper electrode 31, the wall part of the process vessel 11, and an earth, in this order. By means of this operation of the plasma processing apparatus 1, the wafer W fixed on the stage 2 is subjected to an etching by the plasma.

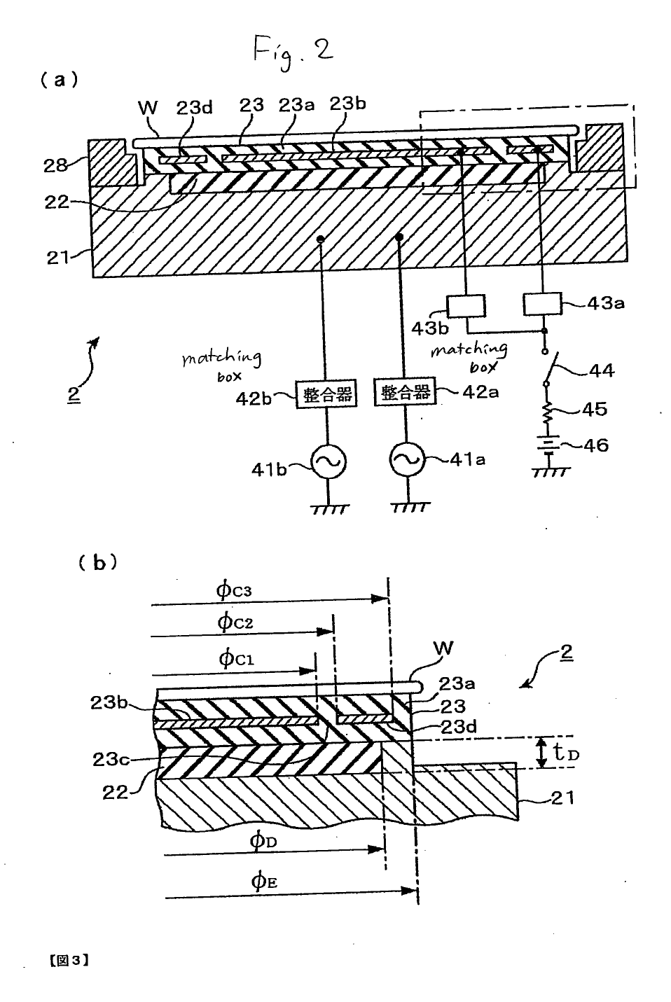

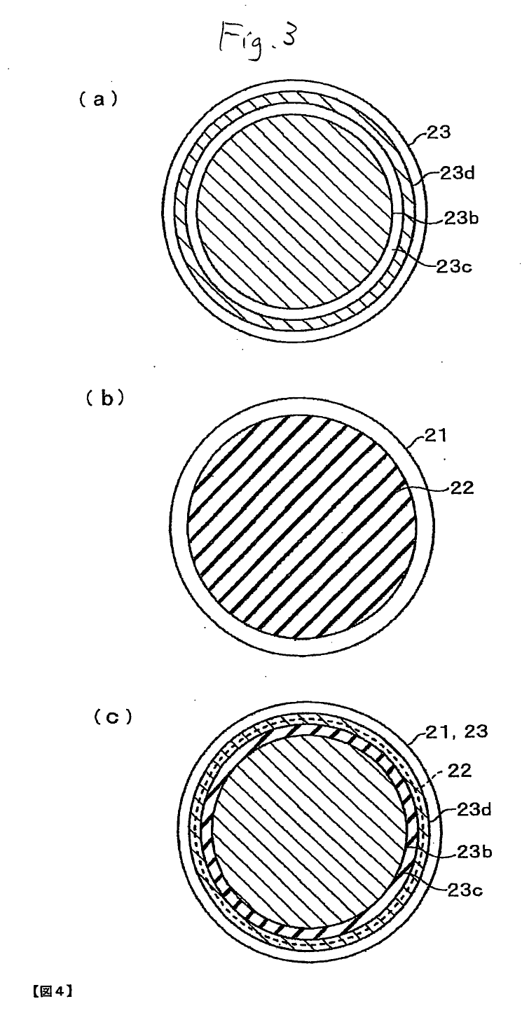

With reference to FIGS. 2 to 3, the stage 2 in this embodiment is described in detail below. In the longitudinal sectional views of the stage 2 shown in FIGS. 2A and 2B, illustration of the cooling medium passage 26, the through-hole 25 for a backside gas, and soon are omitted.

As shown in FIG. 2(a), the dielectric layer 22 is embedded in a center part of an upper surface of the lower electrode 21. The dielectric layer 22 has a function for lowering an electric potential of a plasma in a range where the dielectric layer 22 is embedded. For example, the dielectric layer 22 is made of ceramics containing alumina (Al₂O₃) as a principal component and having a dielectric constant of 10. As shown in FIG. 2(b), the dielectric layer 22 is of a discoid shape having a thickness t_{D}=5 mm and a diameter Φ=240 mm.

Next, the electrostatic chuck is described. As shown in FIG. 2(a), the electrostatic chuck 23 has a structure in which an electrode film is interposed between upper and lower insulating films 23a formed by spraying, e.g., alumina. The electrode film is made of an electrode material having a resistivity of about 1.0×10⁻⁴ Ωm. As shown in FIG. 3(a), the electrostatic chuck 23 in this embodiment includes a circular first electrode film 23b, and an annular second electrode film 23d surrounding the first electrode film 23b through a separation area 23c free of electrode film. Namely, the electrode films 23b and 23d are separated to be spaced apart from each other in a radial direction of the stage 2. For example, the first electrode film 23b has a diameter (Φ_{Cl}=158 mm, and a second electrode film 23d has an inner diameter Φ_{C2}=162 mm and an outer diameter Φ_{C3}=298 mm.

As shown in FIG. 2(a), the electrode films 23b and 23d are connected to high impedance circuits 43b and 43a, respectively, to provide independent circuits in terms of radiofrequency. The high impedance circuits 43a and 43b are connected to a common high-voltage direct-current power source 46 via a common switch 44 and a common resistance 45. When a high-voltage direct-current electric power is applied from the high-voltage direct-current power source 46 to the electrode films 23b and 23d, a Coulomb force is generated on the surface of the electrostatic chuck 23. Due to the thus generated Coulomb force, a wafer W is electrostatically absorbed on the upper surface (placing surface) of the electrostatic chuck 23. The high impedance circuits 43a and 43b are circuits which exhibit high impedances as to a radiofrequency supplied to the lower electrode 21 (lawpass filter: LPF). In this embodiment, since the first and second electrode films 23b and 23d are connected to the common high-voltage direct-current power source 46, there are arranged the high impedance circuits 43a and 43b in order to insulate the electrode films 23b and 23d from each other as to a radiofrequency. A method of insulting the electrode films 23b and 23d from each other as to a radiofrequency is not limited to the above example. For example, a high-voltage direct-current power source and a high impedance circuit (LPF) may be connected to each of the electrode films 23b and 23d. Alternatively, by connecting the two electrode films 23b and 23d with a pattern of an electrode film providing an inductor component, and by connecting only the outside electrode film 23d to the high-voltage direct-current power source 46 via the high impedance circuit 43a, the electrode films 23b and 23d may be insulated from each other as to a radiofrequency.

As shown in the enlarged longitudinal sectional view in FIG. 2(b), under the state in which the lower electrode 21, the dielectric layer 22, and the electrostatic chuck 23 are laminated, a positional relationship of the dielectric layer 22 and the electrode films 23b and 23d of the electrostatic chuck 23 is set in such a manner that an outer edge of the dielectric layer 22 is positioned outside an outer edge of the electrode film 23b. That is to say, as shown in FIG. 3(c), when a plane of vertical projection of the dielectric layer 22 and planes of vertical projection of the electrode films 23b and 23d relative to the placing surface of the wafer W are viewed from the placing surface, the outer edge of the dielectric layer 22 is positioned outside an inner edge of the separation area 23c which is formed between the separated electrode films 23b and 23d.

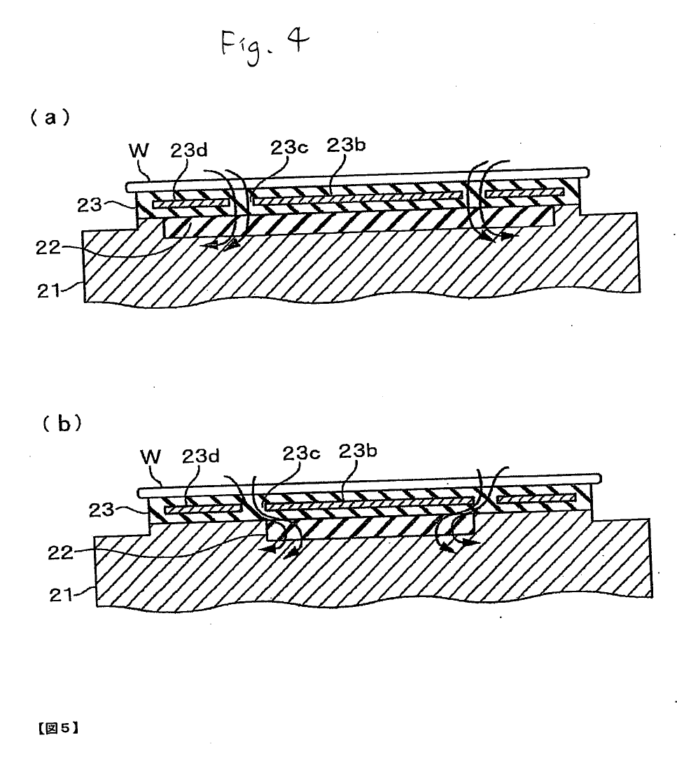

An operation of the stage 2 in this embodiment is described below. As shown in FIG. 4(a), a part of the radiofrequency current, which has been supplied from the first radiofrequency power source 41a and propagated through the surface of the lower electrode 21, leaks from the surface of the wafer W to the electrostatic chuck 23. At this time, since the electrode films 23b and 23d embedded in the electrostatic chuck 23 are separated to be spaced apart from each other in the radial direction, the radiofrequency is allowed to reach the dielectric layer 22, as indicated by the arrows. Thus, in a region where the dielectric layer 22 is embedded, the radiofrequency can plunge more deeply as compared with the other regions, so that an effect of lowering an electric potential of a plasma in the region can be obtained.

By the operation as described above, even the stage 2 of a type using the electrostatic chuck 23 for fixing a wafer W can provide an effect of lowering an electric potential of a plasma with the use of the dielectric layer 22. Unless the dielectric layer 22 exerts the effect, the electric field strength distribution has a chevron-shaped peak. However, due to exercitation of the effect of the dielectric layer 22, the peak in the electric field strength distribution can be flattened. Thus, an excellent uniformity of electron density in a plasma can be obtained, and an in-plane uniformity of a plasma process such as etching process can be significantly improved.

Provided that the outer edge of the dielectric layer 22 is positioned outside the inner edge of the separation area 23c, the dielectric layer 22 can exert the effect of uniformizing the electric field. That is, as shown in FIG. 5, the scope of the present invention includes another structure of the stage 2 in which the dielectric layer 22 has a shorter diameter so that the outer edge of the dielectric layer 22 is positioned between the inner edge and the outer edge of the separation area 23c.

Next, a structure of a stage 2 in a second embodiment of the present invention is described below. In the second embodiment, an outer edge of a dielectric layer 22 is positioned just below an inner edge of a separation area 23c. The second embodiment differs in this point from the first embodiment in which the outer edge of the dielectric layer 22 is positioned outside the inner edge of the separation area 23c.

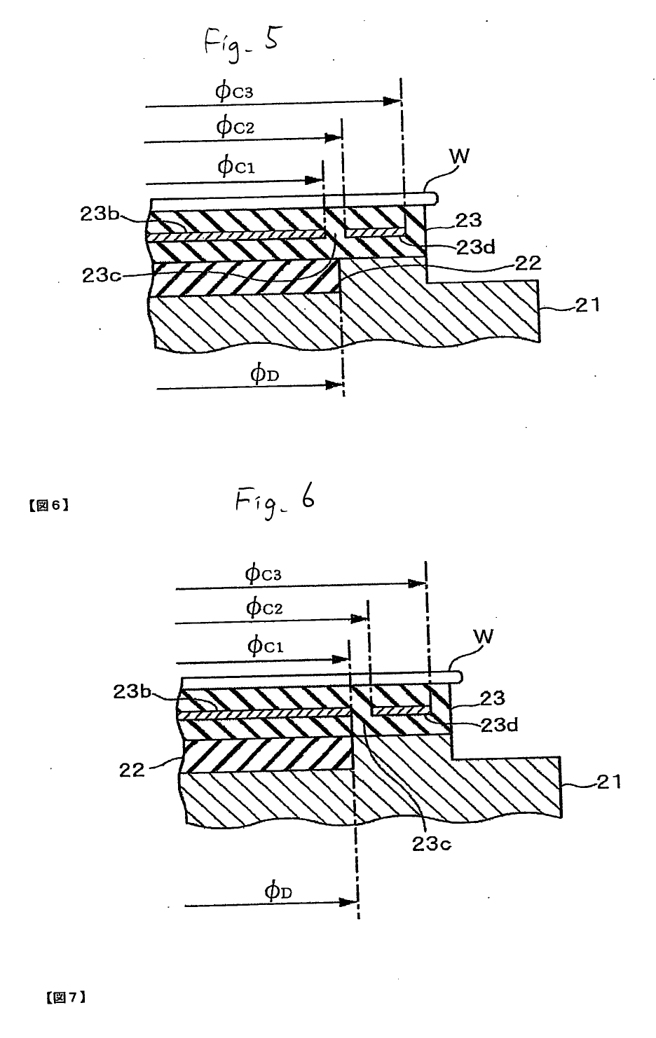

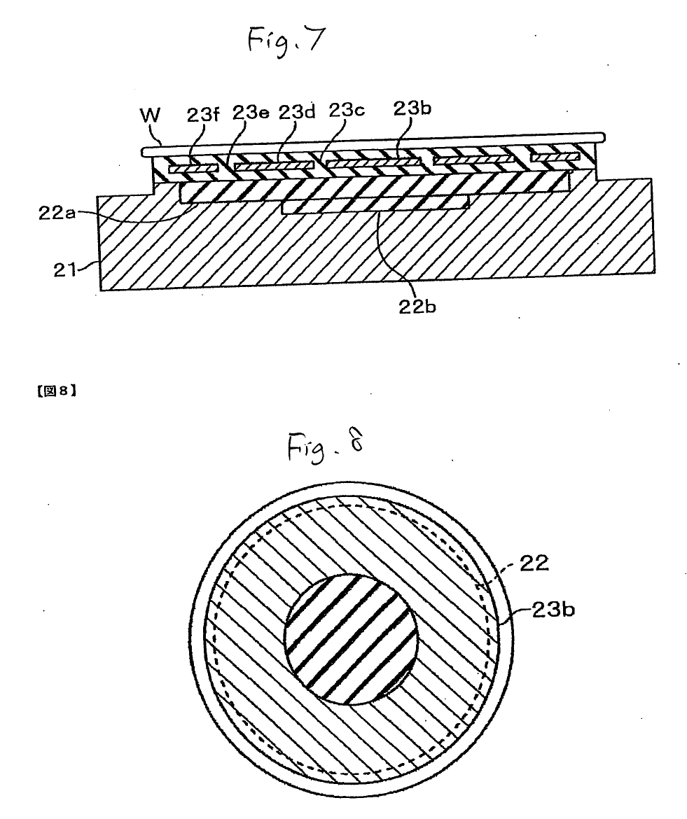

To be specific, as shown in FIG. 6, for example, the dielectric layer 22 and a first electrode film 23b are formed to have substantially the same dimensions. The stage 2 is assembled such that center parts of the dielectric layer 22 and the first electrode film 23b correspond to each other. As a result, the outer edge of the dielectric layer 22 is positioned right below the inner edge of the separation area 23c.

As shown by the arrows in FIG. 4(b), since the outer edge of the dielectric layer 22 is positioned immediately below the inner edge of the separation space 23c, a radiofrequency from the surface of a wafer W is allowed to reach the dielectric layer 22. In a region where the dielectric layer 22 is embedded, since the radiofrequency plunges more deeply as compared with the other regions, an electric potential of a plasma in the region is lowered. In terms of formation of a uniform plasma, the electrostatic chuck 23 may not have a second electrode film 23d.

In addition, the number of the dielectric layer for lowering an electric potential of a plasma is not limited to one. For example, as shown in FIG. 7, it is possible to adopt a structure in which a second dielectric layer 22b is embedded under a first dielectric layer 22a such that an outer edge of the second dielectric layer 22 is positioned inside the outer edge of the first dielectric layer 22a. Also in this case, since a radiofrequency is allowed to more deeply plunge into the dielectric layers, a peak region of an electric field strength distribution, which is of a chevron shape unless the effect of the dielectric layer is exerted, can be sufficiently flattened.

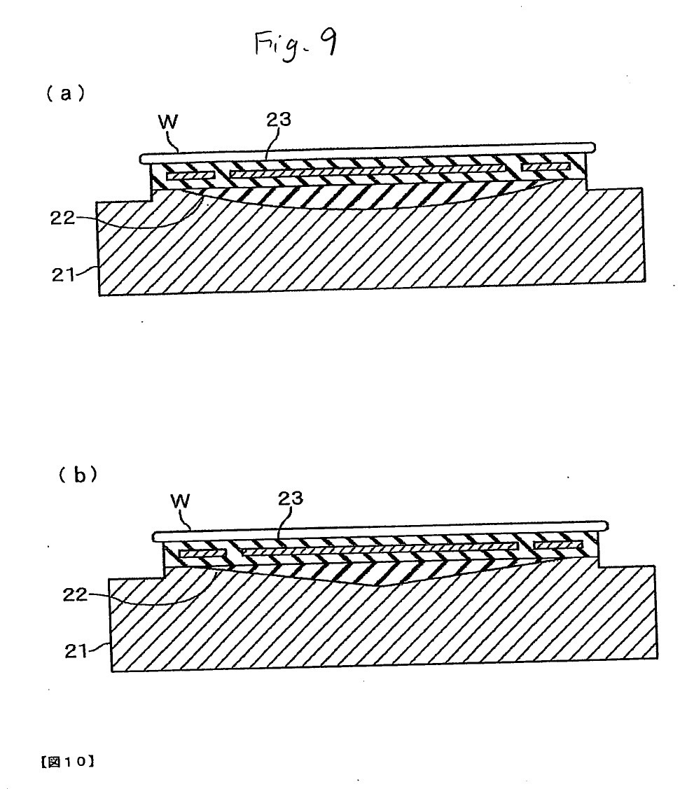

As shown in FIG. 8, as a modification of the present embodiment, the electrode film 23b of the electrostatic chuck may have a hole formed in a position corresponding to a center part of the stage. In this structure, the dielectric layer 22 is positioned below the hole.

A shape of the dielectric layer 22 is not limited to a columnar shape as in the above embodiment. For example, the dielectric layer 22 may be of a domed shape as shown in FIG. 9(a) or a circular conic shape as shown in FIG. 9(b). By making a thickness of the circumferential part of the dielectric layer 22 smaller than that of the central part thereof, the electric field strength is more weakened in the central part than in the circumferential part, so that a more flattened electric filed distribution can be obtained. In this case, there may be formed three or more separated electrode films so as to form a plurality of separation areas.

In addition, since a general coefficient of linear expansion of ceramics, which is used as a dielectric layer, is 2×10⁻⁶/° C. to 11×10⁻⁶/° C., it is preferable to select a conductive member whose coefficient of linear expansion is approximate to the above value, for forming an electrode.

### EXAMPLES

(Simulation 1)

An apparatus was modeled based on the plasma processing apparatus of a parallel plate type as shown in FIG. 1, and simulations were conducted to estimate electric filed strength distributions on wafers.

A. Simulation Conditions

Resistivity of electrode films 23b and 23d: 1.0×10⁻⁶ Ωm

Resistivity of wafer W: 5.0×10⁻² ΩM

Resistivity of plasma: 1.5 Ωm

Relative dielectric constant ∈ of dielectric layer 22: 10

Applied power: 2 kW (with two frequencies of 40 MHz and 100 MHz)

Under these conditions, an electric field strength distribution in a radial direction was simulated with respect to a wafer W placed on a placing surface of the stage 2 of each of the below examples and comparative examples.

### Example 1

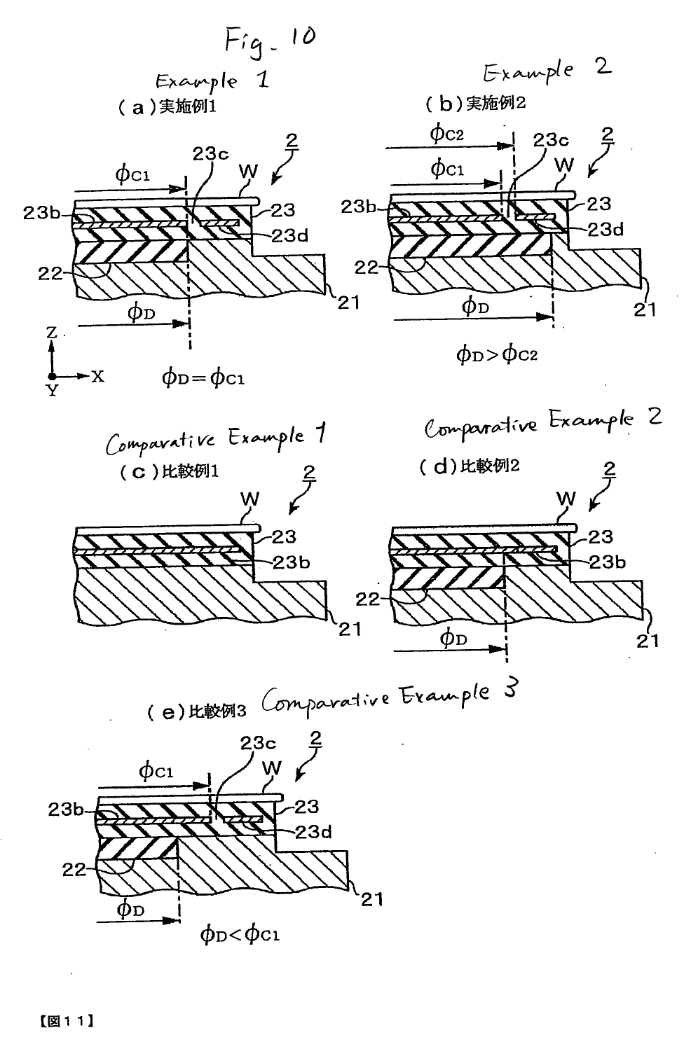

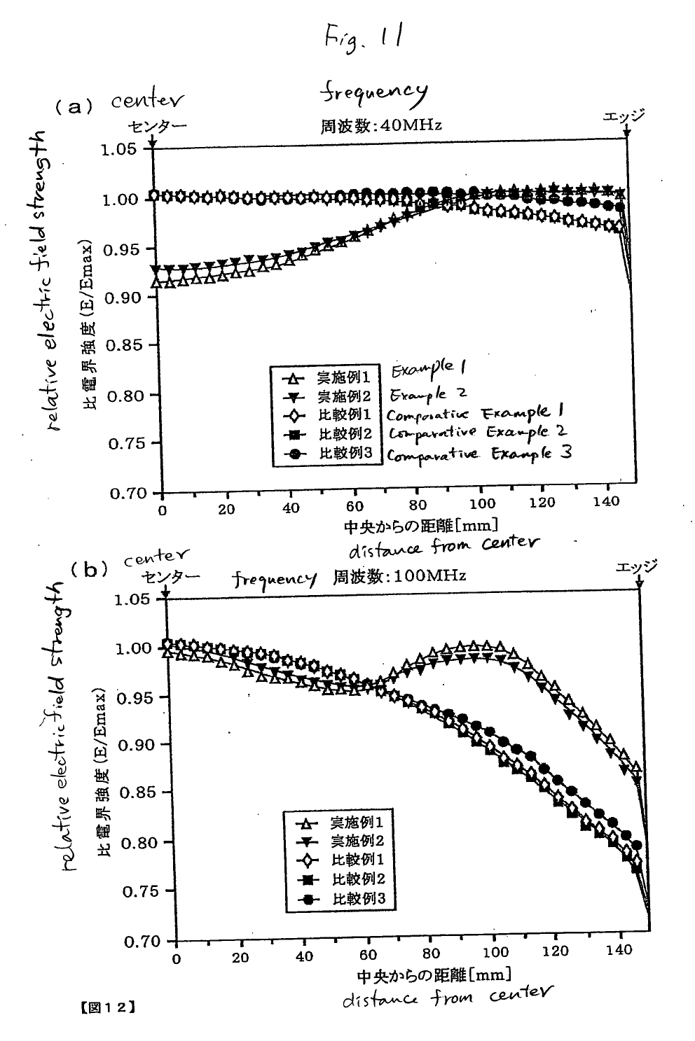

As shown in FIG. 10(a), a simulation was conducted with a stage 2 of the same structure as that of the second embodiment.

The first electrode film 23b had a diameter Φ_{C1}=158 mm. The second electrode film 23d had an inner diameter Φ_{C2}=162 mm, and an outer diameter Φ_{C3}=298 mm. The dielectric layer had a diameter D=158 mm.

### Example 2

As shown in FIG. 10(b), a simulation was conducted with a stage 2 of the same structure as that of the first embodiment.

Dimensions of the first electrode film 23b and the second electrode film 23d were the same as those of Example 1. A diameter Φ_{D} of the dielectric layer 22 was 240 mm.

### Comparative Example 1

As shown in FIG. 10(c), a simulation was conducted with a stage 2 in which no dielectric layer 22 was embedded and the electrode film 23b of the electrostatic chuck 23 was not separated.

### Comparative Example 2

As shown in FIG. 10(d), a simulation was conducted with a stage 2 in which the dielectric layer 22 was embedded and the dielectric film 23b was not separated. A diameter Φ_{D} of the dielectric layer 22 was 160 mm.

### Comparative Example 3

As shown in FIG. 10(e), a simulation was conducted with a stage 2 in which the electrode films 23b and 23d were separated from each other, which is similar to the first and second embodiments, but a diameter of the dielectric layer 22 was smaller than that of the dielectric film 23b so that an outer edge of the dielectric layer 22 was positioned inside an inner edge of the separation area 23c.

Dimensions of the first electrode film 23b and the second electrode film 23d were the same as those of Example 1. A diameter Φ_{D} of the dielectric layer 22 was 100 mm.

B. Simulation Results

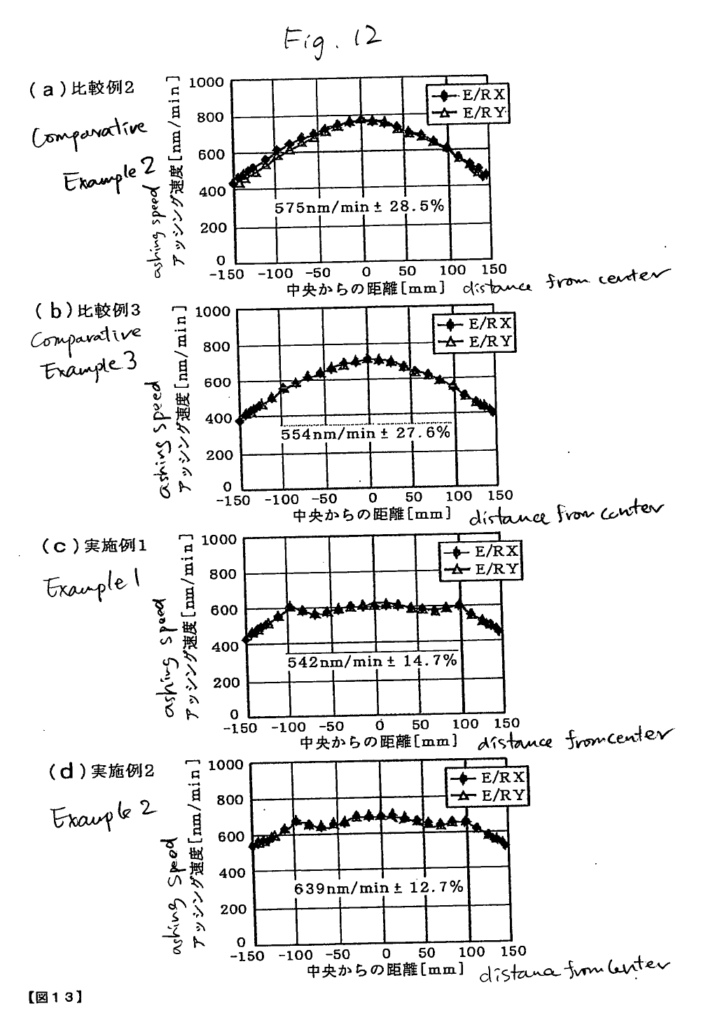

FIGS. 11A and 11B show simulation results of the electric field strength distributions in the respective Examples and Comparative Examples. FIG. 11(a) shows simulation results in which a radiofrequency of 40 MHz was applied. FIG. 11(b) shows simulation results in which a radiofrequency of 100 MHz was applied. The horizontal axis in each graph shows a radial distance [mm] from a center of the wafer W when the center is “0”. The vertical axis shows a “relative electric field strength (=electric field strength E on each position obtained by the simulation/max value Eₘₐₓ out of all positions of the simulation result)”. A simulation result of Example 1 is shown by plotting triangles (□). A simulation result of Example 2 is shown by plotting inverted triangles (▾). A simulation result of Comparative Example 1 is shown by plotting rhombi (⋄). A simulation result of Comparative Example 2 is shown by plotting squares (▪). A simulation result of Comparative Example 3 is shown by plotting circles (●).

As to Comparative Example 1 in which no dielectric layer 22 was embedded, the simulation results show that, in both cases when the frequencies of a radiofrequency were 40 MHz and 100 MHz, the electric field strength distribution had a maximum electric field strength at a center region of the wafer W ((⋄) in FIGS. 11(a) and 11(b)). Similar to Comparative Example 1, as to Comparative Example 2 (▪) in which the dielectric layer 22 was embedded but the electrode film 23b was not separated, and as to Comparative Example 3 (●) in which the electrode film 23b and 23d were separated from each other but a diameter of the dielectric layer 22 was smaller than the electrode film 23b, each electric field strength distribution had a maximum electric field strength at the center region of the wafer W. It can be said that these results show that the dielectric layer 22 did not work well because of the influences of the electrode film 23b of the electrostatic chuck positioned between the wafer W and the dielectric layer 22, whereby the effect of the dielectric layer 22 for lowering an electric potential of a plasma could not be produced.

Contrary to these Comparative Examples, a simulation result of Example 1 corresponding to the second embodiment shows, when the a radiofrequency of 40 MHz was applied, the electric field strength distribution had a maximum electric field strength at a region relatively near the outer edge of the wafer W, i.e., at a region distant from the center of the wafer W by about 120 mm ((Δ) in FIG. 11(a)). When a radiofrequency of 100 MHz was applied, the electric field strength distribution had maximum electric field strengths at the center region of the wafer W and at a region relatively near the outer edge of the wafer W, i.e., at a region distant from the center of the wafer W by about 100 mm ((Δ) in FIG. 11(b)). Simulation results of Example 2 corresponding to the first embodiment show electric field distributions substantially similar to those of Example 1, in both cases where the frequencies were 40 MHz and 100 MHz ((▾) in FIGS. 11(a) and 11(b)).

That is to say, different from the results of Comparative Examples 1 to 3, the simulation results of Examples 1 and 2 are not the electric filed strength distributions in which an electric field strength is high at only the center region of the wafer W. It can be said that these results show that, even when the electrode film 23b of the electrostatic chuck is positioned between the wafer W and the dielectric layer 22, the dielectric layer 22 embedded in the lower electrode 21 could work well due to the presence of the separation area 23c, i.e., an effect of lowering an electric potential of a plasma could be produced in a region where the dielectric layer 22 was embedded.

### Experiment 1

Stages 2 of the same structure as those shown in Examples 1 and 2 and Comparative Examples 2 and 3 in (Simulation 1) were manufactured, and influences given to actual plasma processes by the differences in structure of the stages 2 were examined.

A. Experiment Method

In this experiment, there were used plasma processing apparatuses of a parallel plate type as shown in FIG. 1 which respectively incorporated the stages 2 having the same structures as those shown in Examples 1 and 2 and Comparative Examples 2 and 3.

At first, a wafer W on which a resist film had been applied was placed on a placing surface of each stage 2, and a plasma was generated to ash the resist film. A pressure in the process vessel 11 was 7 Pa (5 mTorr). An O₂ gas (supplied at 100 sccm) was used as a process gas. A radiofrequency for generating plasma has a frequency of 100 MHz, and a power of 2 kW. After the ashing process was performed for a predetermined period of time, ashing speeds per unit time were calculated by measuring a thickness of the resist film at predetermined measuring points on the wafer W.

B. Experiment Results

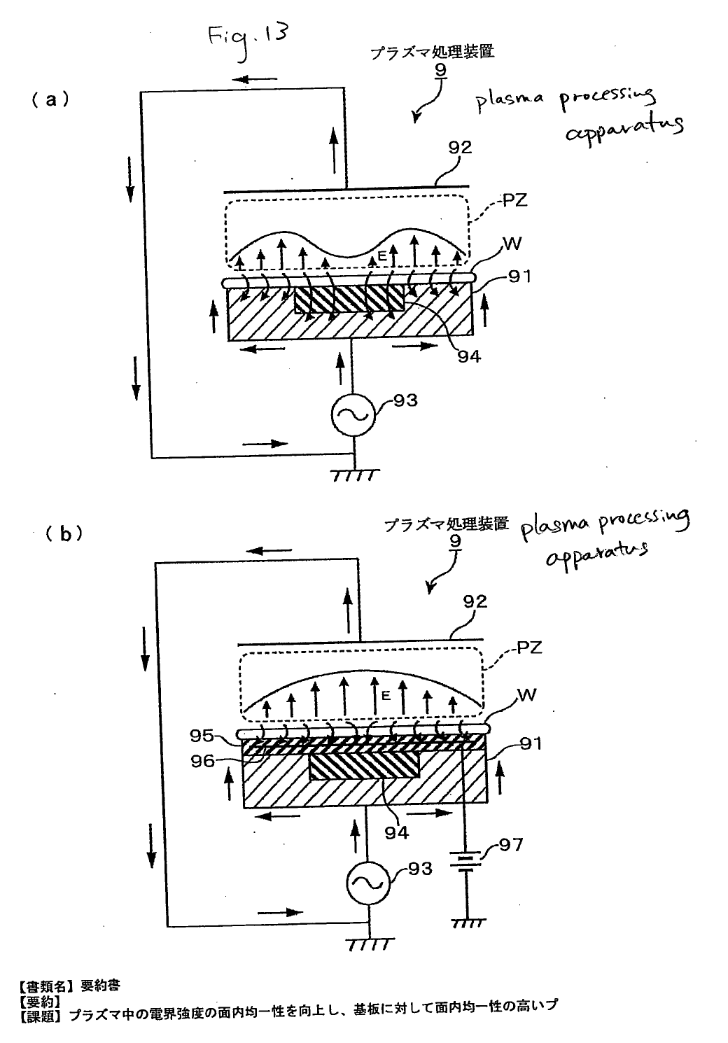

FIGS. 12(a) to 12(d) respectively show results in which ashing speeds calculated by experiment results for each measuring point on the wafer W are plotted. FIGS. 12(a) and 12(b) show the experiment results of the stages 2 corresponding to Comparative Examples 2 and 3, respectively. FIGS. 12(c) and 12(d) show the experiment results of the stages 2 corresponding to Examples 1 and 2, respectively.

The horizontal axis of each graph shows a distance [mm] of the wafer W from a center of the wafer W, when coordinate axes are set in the directions shown in FIG. 10(a), i.e., in an X-axis direction (right and left direction in the view, with the right side being positive) and in a Y-axis direction (a direction from front to behind in the view, with the behind side being positive). The vertical axis in each graph shows an ashing speed [nm/min]. In the respective experiment results, an ashing speed in the X-axis direction is plotted by rhombi (♦), and an ashing speed in the Y-axis direction is plotted by triangles (Δ). The numbers described in each graph show an average value of an ashing speed under each experiment condition, and a relative variation width [%] of the experiment result relative to the average value. In view of the experiment results, in all the conditions (Comparative Example 2, Comparative Example 3, Example 1, and Example 2), no difference in ashing speed was found depending on the X-axis direction and the Y-axis direction, i.e., the ashing speed distribution was radially symmetric relative to the center of the wafer W.

As shown in FIGS. 12(a) and 12(b), the experiment results of Comparative Example 2 and Comparative Example 3 show distributions in which the ashing speed became maximum at the center region of the wafer W. It can be said that the reason therefor is, since the electrode film 23b was not separated so that the separation area 23c was not formed, which structure blocked an influence given by the dielectric layer 22 on a plasma, the effect of the dielectric layer 22 for lowering an electric potential of the plasma could not be produced.

On the other hand, in view of the experiment results of Example 1 and Example 2, as shown in FIGS. 12(c) and 12(d), no peak of the ashing speed was found at the center region of the wafer W. As compared with the variation widths of Comparative Example 2 and Comparative Example 3 (27.6% to 28.5%), the variation widths of Example 1 and Example 2 were substantially reduced by half (12.7% to 14.7%). These results are correspondent to the simulation results of the electric field strength distributions in the respective Examples. Namely, it can be said that, even when the electrode film 23b of the electrostatic chuck was positioned between the wafer W and the dielectric layer 22, the dielectric layer 22 embedded in the lower electrode 21 could acts on a plasma through the separation area 23c, so as to lower an electric potential of the plasma in a region where the dielectric layer 22 was embedded, and, therefore, a peak in the electric field strength distribution, which may draw a chevron curve without the effect of the dielectric layer 22, could be flattened. The condition providing the above-described effect is not limited to the frequency of a radiofrequency power used in the simulations and experiments. For example, even when a radiofrequency of 13 MHz or 27 MHz is applied, the same effect can be provided.

### BRIEF DESCRIPTION OF THE DRAWINGS

[FIG. 1] A schematic longitudinal sectional view of a plasma processing apparatus including a stage according to a first embodiment of the present invention.

[FIG. 2] A schematic longitudinal sectional view of the stage in the first embodiment of the present invention.

[FIG. 3] A view illustrating a pattern (shape) of an electrode film of an electrostatic chuck, a dielectric layer for lowering an electric potential of a plasma, and a positional relationship between the electrode films and the dielectric layer.

[FIG. 4] A view explaining an operation of the stage.

[FIG. 5] A view showing a modification of the stage in the first embodiment.

[FIG. 6] A longitudinal side view showing an example of the stage in the second embodiment.

[FIG. 7] A schematic longitudinal sectional view of an example of stage in which a plurality of dielectric layers are laminated.

[FIG. 8] A view illustrating a pattern (shape) of another electrode film.

[FIG. 9] A view illustrating modifications of the dielectric layer.

[FIG. 10] longitudinal sectional views of structures of stages used in simulations on electric field strength distribution in Examples and Comparative Examples.

[FIG. 11] Graphs of results of the simulations on electric field strength distribution.

[FIG. 12] Graphs of results of experiments on in-plane uniformity of an ashing process as an example of a plasma process.

[FIG. 13] views illustrating a conventional plasma processing apparatus

### DESCRIPTION OF REFERENCE NUMBERS

PZ plasma
W wafer
1 plasma processing apparatus
2 stage
9 plasma processing apparatus
11 process vessel
11a upper chamber
11b lower chamber
12 exhaust port
13 exhaust pipe
14 exhaust system
15 loading/unloading port
16 gate valve
17 support case
18 baffle plate
21 lower electrode
21a support table
22 dielectric layer
22a first dielectric layer
22b second dielectric layer
23 electrostatic chuck
23a insulation film
23b electrode film (first electrode film)
23c separation area (first separation area)
23d electrode film (second electrode film)
23e second separation area
23f third electrode film
24 insulating member
25 through-hole
26 coolant medium passage
27 gas passage
28 focus ring
31 upper electrode
32 gas-supplying hole
33 gas-introducing pipe
35 process-gas supplying source
41a first radiofrequency power source (radiofrequency power source)
41b second radiofrequency power source
42a, 42b matching box
44 switch
45 resistance
46 high-voltage direct-current power source
47a, 47b multipole ring magnet
91 lower electrode
92 upper electrode
93 radiofrequency power source
94 dielectric layer
95 electrostatic chuck
96 electrode film
97 high-voltage direct-current power source

1. A stage for a plasma processing apparatus, the stage being configured to place on a placing surface thereof a substrate to be processed, the stage comprising:
a conductive member connected to a radiofrequency power source, the conductive member serving as an electrode for generating a plasma and/or as an electrode for drawing ions from a plasma;
a dielectric layer covering a center part of an upper surface of the conductive member, for making uniform a radiofrequency electric field applied to a plasma through a substrate to be processed placed on the placing surface; and
an electrostatic chuck laminated on the dielectric layer, the electric chuck having a plurality of electrode films embedded therein, the electrode films being separated apart from each other in a radial direction of the stage to allow passage of a radiofrequency;
wherein an outer edge of the dielectric layer is positioned right below or outside an inner edge of at least one separation area of the separated electrode films, and
the separated electrode films are insulated to each other as to a radiofrequency.

2. The stage for a plasma processing apparatus according to claim 1, wherein
a plurality of dielectric layers are laminated as the dielectric layer,
a lower dielectric layer of the plurality of dielectric layers is located such that an outer edge of the lower dielectric layer is positioned inside relative to that of an upper dielectric layer, and
the number of the separated electrode films is larger than the number of the laminated dielectric layers at least by one.

3. A stage for plasma processing apparatus, the stage being configured to place on a placing surface thereof a substrate to be processed, the stage comprising:
a conductive member connected to a radiofrequency power source, the conductive member serving as an electrode for generating a plasma and/or as an electrode for drawing ions from a plasma;
a dielectric layer covering a center part of an upper surface of the conductive member, for making uniform a radiofrequency electric field applied to a plasma through a substrate to be processed placed on the placing surface; and
an electrostatic chuck laminated on the dielectric layer, the electric chuck having a hole formed in a position corresponding to a center part of the stage to allow passage of a radiofrequency;
wherein the dielectric layer is positioned below the hole.

4. The stage for a plasma processing apparatus according to one of claims 1 to 3,
wherein the dielectric layer is formed into a columnar shape.

5. The stage for a plasma processing apparatus according to one of claims 1 to 3,
wherein a thickness of a circumferential part of the dielectric layer is smaller than a thickness of a center part of the dielectric layer.

6. The stage for a plasma processing apparatus according to one of claims 1 to 5,
wherein a frequency of the radiofrequency supplied from the radiofrequency power source is not less than 13 MHz.

7. A plasma processing apparatus comprising:
a process vessel configured to subject a substrate to be processed to a plasma process;
a process-gas introducing part for introducing a process gas into the process vessel;
the stage for a plasma processing apparatus according to one of claims 1 to 6, the stage being disposed in the process vessel;
an upper electrode disposed in the process vessel, the upper electrode being positioned above the stage and opposed thereto; and
a unit for evacuating an inside of the process vessel to create therein a vacuum.
